(19) United States
(12) Patent Application Publication
(10) Pub. No.: US 2010/0127299 A1
(43) Pub. Date: May 27, 2010

(54) Actively Cooled LED Lighting System and Method for Making the Same

(75) Inventors: Robert David Smith, Fayetteville, GA (US); Evans Thompson, Marietta, GA (US); Scott Wegner, Peachtree City, GA (US)

Correspondence Address: KING & SPALDING, 1180 PEACHTREE STREET , NE, ATLANTA, GA, 30309-3521, US

(73) Assignee: Cooper Technologies Company, Houston, TX (US)

(21) Appl. No.: 12/277,769

(22) Filed: Nov. 25, 2008

(51) Int. Cl. H01L 31/024; H01L 21/02; H01L 31/18

(52) U.S. Cl. 257/99; 438/26; 257/E21.002; 257/E31.131; 257/E31.001

(57) ABSTRACT

A lighting system can comprise one or more light emitting diodes (“LEDs”) that emit substantially white light and a thermoelectric cooler (“TEC”) for maintaining the LEDs within a temperature range. The TEC can comprise an electrical circuit that includes two different semiconductors or two dissimilar metals that provide cooling when electrically energized. The electrical circuit can adjoin or touch one side of a plate, sheet, wafer, or substrate of material, such as ceramic, that insulates electricity and conducts heat. In operation, the electrical circuit can cool the plate or actively transfer heat from the plate. The LEDs can adjoin or touch the side of the plate that is opposite the electrical circuit. Thus, a TEC circuit can contact one surface of a thin piece of ceramic material, while an LED contacts the opposite surface.

### FIELD OF THE INVENTION

The present invention relates to illumination systems that utilize light emitting diodes (“LEDs”) to provide light, and more specifically to LED illumination systems that incorporate active cooling, so the LEDs operate in a favorable temperature range.

### BACKGROUND

LEDs offer benefits over incandescent, high energy discharge (“HID”) and fluorescent lights as sources of illumination. Such benefits include high energy efficiency and longevity. To produce a given output of light, an LED consumes less electricity than an incandescent or a fluorescent light. And, in general, the LED will last longer before failing.

The level of light that a typical LED outputs depends upon the amount of electrical current supplied to the LED and the operating temperature of the LED. Thus, the intensity of light emitted by an LED changes when electrical current is constant and the LED's temperature varies and when electrical current varies and temperature remains constant. Operating temperature also impacts the usable lifetime of most LEDs. Accordingly, an LED typically has a temperature range that can sustain efficient operation for many years without failure.

The conventional technologies available for maintaining an LED at a desired operating temperature are generally limited. Conventional technologies frequently involve inefficient manufacturing procedures, can be costly to implement, are often inflexible, and may lack sufficient finesse for maintaining an LED at optimal operating conditions.

Accordingly, to address these representative deficiencies in the art, what is needed is an improved technology for operating an LED at a desired temperature or within a specified range of temperatures. Moreover, a need exists for applying temperature control or thermal regulation to an LED in a manner that supports cost-effective manufacturing. Such need encompasses not only product architectures that promote manufacturability, but also processes for fabrication and manufacturing. Another need exists for processes and designs that tightly integrate thermal regulation or cooling with an LED. Yet another need exists for efficiently removing heat generated by an LED. Still another need exists for attaching a cooling circuit and an LED drive circuit to one substrate, for example to reduce size, to control cost, to minimize manufacturing steps, or to improve flexibility. A capability addressing one or more of the aforementioned needs, or some similar want in the field, would advance LED lighting.

### SUMMARY

In one aspect of the present invention, a lighting system, apparatus, or device can comprise one or more LEDs. The LEDs can emit or produce visible light, for example light that is white, red, blue, green, purple, violet, yellow, multicolor, etc. Thus, the light can have a wavelength or frequency that a typical human being can perceive visually. Furthermore, the emitted light can have spectral content invisible to a human observer, for example in an ultraviolet or near-ultraviolet spectral range. The emitted light can comprise photons, luminous energy, electromagnetic waves, radiation, or radiant energy.

In addition to one or more LEDs, the lighting system can comprise a system that thermally regulates or controls at least one LED, for example via cooling or extracting heat from the LED. Accordingly, a thermal regulation system can provide the LED with a temperature or a thermal condition that benefits the LED's operation, for example enhancing efficiency, reducing risk of failure, providing desirable spectral content, or extending the LED's useful life.

The thermal regulation system can comprise a substrate, at least part of which is electrically insulative (or inhibits flow of electricity) and is thermally conductive (or promotes heat transfer). The term “substrate,” as used herein, generally refers to a material, or an integrated combination of materials, upon which circuits, circuit elements, LEDs, conductors, or components that are electrical (or optical, semiconductor, electronic, etc.) can be mounted. A substrate can comprise a plate, wafer, sheet, or material having at least one flat surface, to name a few possibilities. Moreover, a substrate can comprise a base material that is coated, plated, layered, deposited, or filmed with another material. The base material can comprise an electrically insulating material, while the coating can comprise a metallic plating, for example. Candidate base materials for the substrate of the thermal regulation system can comprise ceramic, alumina, aluminum oxide, aluminum nitride, boron nitride, diamond, silicon dioxide, or some other inorganic substance (not an exhaustive list). As an alternative to applying a coating on the base material, the substrate can be uncoated.

An electrical circuit that cools the substrate can be attached to one side (or face) of the substrate. That cooling electrical circuit can comprise at least two different materials, which may be dissimilar metals or semiconductors, cooperatively extracting heat from the substrate in response to a flow of electricity. The cooling electrical circuit, which can be viewed as a type of heat pump, can cool via thermal electric (“TE”) cooling or via the Peltier effect, for example. One of the two different materials, or some other portion of the cooling electrical circuit that conducts electricity, can adjoin, contact, or touch that side of the substrate.

The LED can be mounted to another side (or face) of the substrate (e.g. opposite the electrical cooling circuit), for example via soldering to a metal overcoat. In this configuration, the substrate can provide an electrical barrier or electrical insulation between the cooling electrical circuit and another circuit that supplies electrical power to the LED. Meanwhile, the substrate can exhibit low thermal resistance to provide sufficient transmission of heat or thermal conductivity. Via low thermal resistance, the cooling effect of the cooling circuit reaches the LED, and the LED can be cooled efficiently. That is, heat generated by the LED can transmit preferentially through the substrate to facilitate active heat removal by the cooling electrical circuit.

The discussion of cooling or thermally regulating LEDs presented in this summary is for illustrative purposes only. Various aspects of the present invention may be more clearly understood and appreciated from a review of the following detailed description of the disclosed embodiments and by reference to the drawings and the claims that follow. Moreover, other aspects, systems, methods, features, advantages, and objects of the present invention will become apparent to one with skill in the art upon examination of the following drawings and detailed description. It is intended that all such aspects, systems, methods, features, advantages, and objects are to be included within this description, are to be within the scope of the present invention, and are to be protected by the accompanying claims.

### BRIEF DESCRIPTION OF THE DRAWINGS

FIG. 1 is a line drawing of a lighting system comprising an LED and a capability for cooling the LED in accordance with certain exemplary embodiments of the present invention.

FIG. 2 is a cross sectional view of a lighting system, comprising an LED and a capability for cooling the LED, connected to a source of electrical power in accordance with certain exemplary embodiments of the present invention.

FIG. 3 is a line drawing of an exemplary cooling system for a lighting system in accordance with certain embodiments of the present invention.

FIG. 4 is functional block diagram of a thermally regulated lighting system that comprises an LED and a feedback loop, in accordance with exemplary embodiments of the present invention.

FIG. 5 is flowchart of a process for fabricating a lighting system comprising an LED and a capability for cooling the LED, in accordance with exemplary embodiments of the present invention.

FIG. 6 is flowchart of a method of operation of a lighting system comprising an LED and a capability for cooling the LED, in accordance with exemplary embodiments of the present invention.

Many aspects of the invention can be better understood with reference to the above drawings. The elements and features shown in the drawings are not necessarily to scale, emphasis instead being placed upon clearly illustrating the principles of exemplary embodiments of the present invention. Moreover, certain dimensions may be exaggerated to help visually convey such principles. In the drawings, reference numerals designate like or corresponding, but not necessarily identical, elements throughout the several views.

### DETAILED DESCRIPTION OF EXEMPLARY EMBODIMENTS

An exemplary embodiment of the present invention supports operating an LED under conditions that provide efficient or reliable illumination. The LED can be mounted, for example via soldering, solder bumps, or bonding, to a surface of a generally flat piece of material, such as a plate or a sheet of ceramic material. The term “plate”, as used herein, generally refers to a piece or body of material having at least one side or area that is approximately flat or planar, and the term can encompass a piece of material that incorporates layered or laminated structures. Thus, the mounted LED can adjoin, contact, or touch the generally flat piece of material. An electrical circuit for removing heat generated by the LED can also adjoin, contact, or touch the generally flat piece of material, for example on a surface that is opposite the LED. The electrical circuit can comprise one or more components that cool the generally flat piece of material when the circuit is energized.

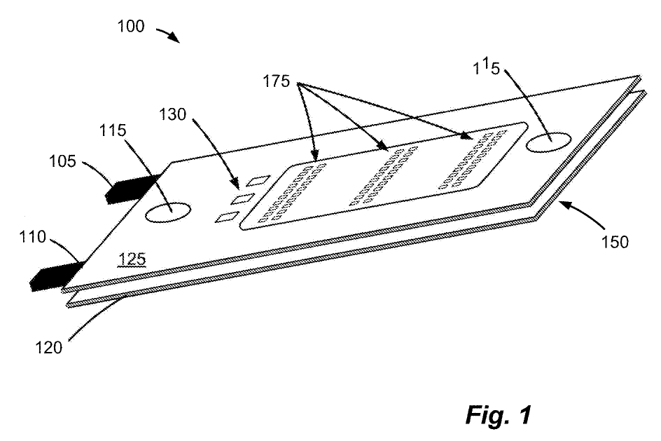

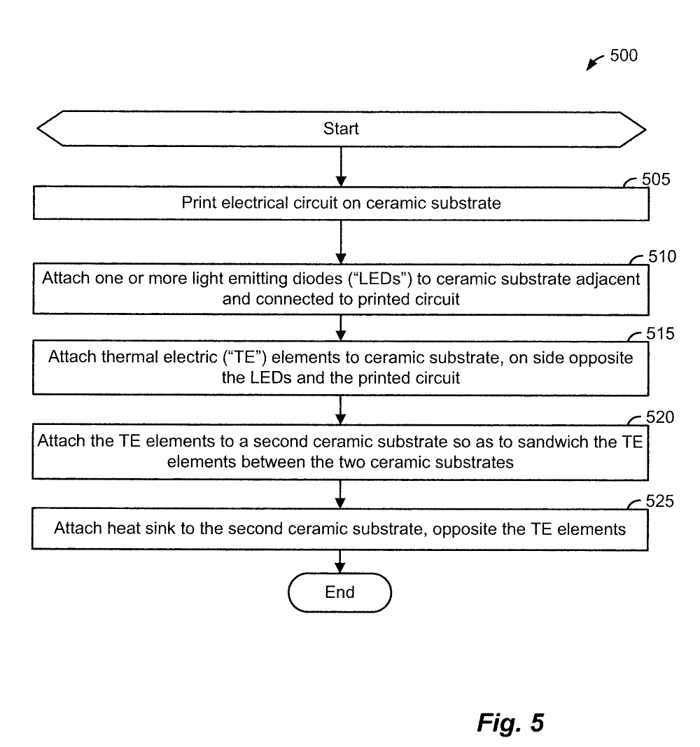

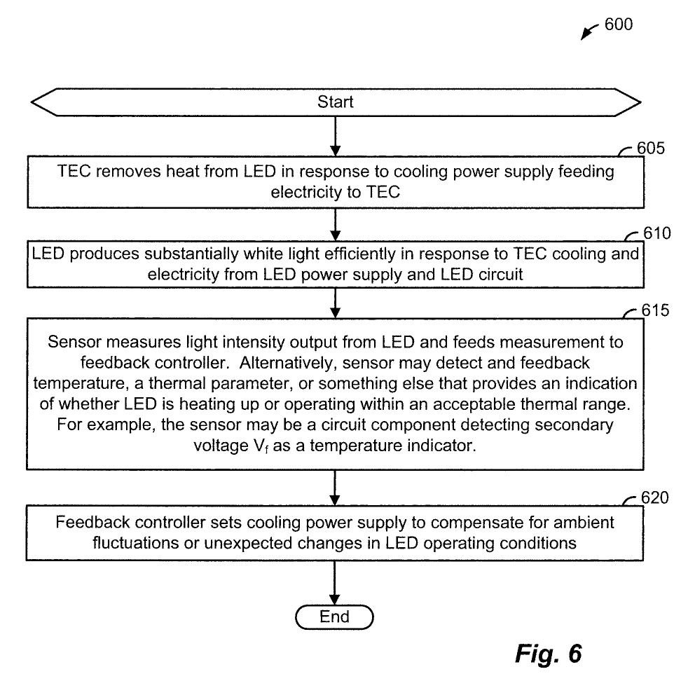

A lighting fixture will now be described more fully hereinafter with reference to FIGS. 1-6, which describe representative embodiments of the present invention. FIGS. 1-4 generally describe an illustrative LED lighting system having a provision for LED cooling. FIGS. 5 and 6 respectively show methods for manufacturing and operating an LED lighting system having a cooling provision.

The invention can be embodied in many different forms and should not be construed as limited to the embodiments set forth herein; rather, these embodiments are provided so that this disclosure will be thorough and complete, and will fully convey the scope of the invention to those having ordinary skill in the art. Furthermore, all “examples” or “exemplary embodiments” given herein are intended to be non-limiting, and among others supported by representations of the present invention.

Turning now to FIG. 1, this figure illustrates a line drawing of an exemplary lighting system 100 comprising an LED 175 and a capability for cooling the LED 175 according to certain embodiments of the present invention. More specifically, the illustrated lighting system 100 comprises an array of LEDs, in six rows. (Other exemplary embodiments may have more or fewer LEDs, LEDs arranged in various arrayed and non-arrayed configurations, and various form factors.) In an exemplary embodiment, the lighting system 100 can be a module of a luminaire or a lighting fixture for illuminating a space or an area that people may occupy or observe.

The term “luminaire”, as used herein, generally refers to a system for producing, controlling, and/or distributing light for illumination. A luminaire can be a system that outputs or distributes light into an environment so that people can observe items in the environment. Such a system could be a complete lighting unit comprising one or more LEDs; sockets, connectors, or receptacles for mechanically mounting and/or electrically connecting components to the system; optical elements for distributing light; and mechanical components for supporting or attaching the luminaires Luminaires are sometimes referred to as “lighting fixtures” or as “light fixtures.” A lighting fixture that has a socket for a light source, but no light source installed in the socket, can still be considered a luminaires That is, a lighting system lacking some provision for full operability may still fit the definition of a luminaires

As discussed in further detail below, the LEDs 175 are mounted on a ceramic substrate 125 that is printed with electrical connections 130 and/or other electrical circuitry features that provide electrical power to the LEDs 175. In addition to functioning as and LED circuit board, the ceramic substrate 125 is also an element of a thermal electric cooler (“TEC”) 150. In terms of composition, the substrate 125, as well as the substrate 120 can comprise alumina, aluminum nitride, boron nitride, diamond, ceramic materials, etc.

The term “ceramic” or “ceramic material”, as used herein, generally refers to an article or material comprising a crystalline or partially crystalline structure or glass that is produced from substantially inorganic, non-metallic substances and is either formed from a molten mass which solidifies on cooling, or is formed and simultaneously or subsequently matured by action of heat. Such non-metallic substances can comprise metal oxides, for example. A ceramic material can have a glazed or unglazed surface. A ceramic article having a coating of a pure metal or some other non-ceramic material would still be a ceramic article. By way of example, ceramic materials can comprise aluminum oxide, alumina, aluminum nitride, barium titanate, bismuth strontium calcium copper oxide, boron carbide, boron nitride, ferrite, lead zirconate titanate, magnesium diboride, sialons, silicon carbide, silicon nitride, steatite, magnesium silicate, titanium oxide, yttrium barium copper oxide, zinc oxide, zirconium dioxide, zirconia, etc.

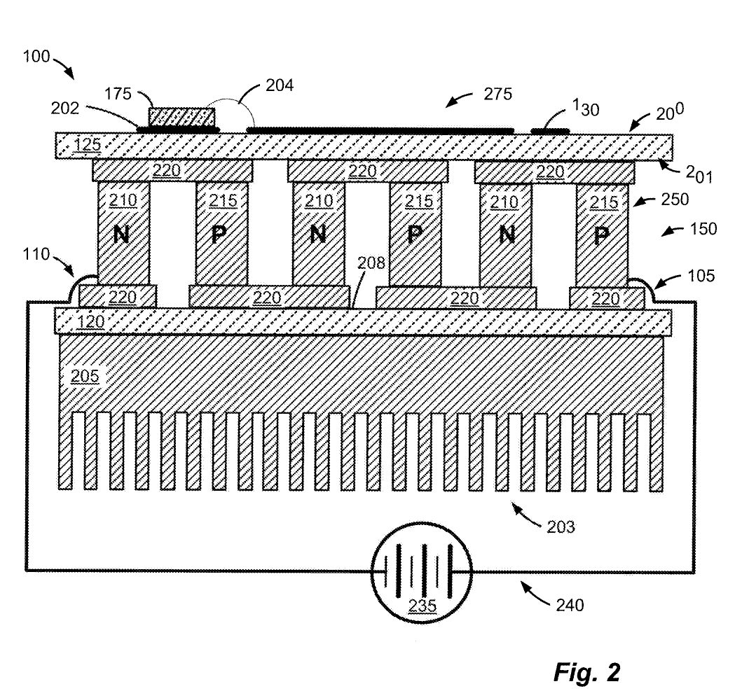

Referring to FIG. 1, a electrical circuit that cools the substrate 125 (and the LEDs attached thereto) is sandwiched between the substrate 125 and another substrate 120. That circuit will be discussed in further detail below with reference to FIG. 2.

As an optional feature, the lighting system 100 comprises two holes 115 extending through the TEC to facilitate mounting in a luminaire or some other lighting fixture or device. Each hole 115 can receive a fastener, such as a screw, that attaches to the luminaires

The TEC 150 receives electricity via the connectors 105, 110, one comprising a positive lead and the other comprising a negative lead. In an exemplary embodiment, the connectors 105, 110 provide mechanical support in addition to electricity. The connectors 105, 110 can be rigidly attached to the TEC 150. In this configuration, the connectors 105, 110 can plug into a female receptacle of a luminaire so the mounting holes 115 can be optional. Alternatively, the connectors 105, 110 can be flexible leads, wires, or pigtails that are coupled to an electrical supply line.

In the exemplary embodiment that FIG. 1 illustrates, the connectors 105, 110 are dedicated electrically to powering the TEC 150. Meanwhile, the LEDs 175 receive electricity via contact pads 130 printed, coated, plated, or otherwise attached to the substrate 125. The lighting system 100 can slide into a groove or slot having associated conductive elements that touch the contact pads 130. Accordingly, a luminaire can comprise spring-loaded, springy, elastic, flexible, or resilient members that contact the contact pads to power the LEDs 175 electrically.

In an alternative exemplary embodiment, the connectors 105, 110 can provide electrical power to both the TEC 150 and the LEDs 175. In this situation, the contact pads 130 can be optional. Accordingly, in one exemplary embodiment, the connectors 105, 110 provide essentially full electrical and mechanical support for mounting and operating the lighting system 100 in a luminaire or some other support structure.

Turning now to FIG. 2, this figure illustrates a cross sectional view of an exemplary lighting system 100, comprising an LED 175 and a capability for cooling the LED 175, connected to a source of electrical power 235 according to certain embodiments of the present invention. In an exemplary embodiment, FIG. 2 illustrates the lighting system 100 of FIG. 1 connected to support facilities that include an electrical circuit 240 and a heatsink 205. The electrical circuit 240 can be an exemplary embodiment of a cooling electrical circuit and will thus often be referred to as the cooling circuit 250 below.

Although the cross sectional view of FIG. 2 illustrates a single LED 175, exemplary embodiments can include either a single LED 175 or multiple LEDs 175. Additional LEDs 175 can furthermore appear in other cross sectional views of the system 100. Accordingly, it is appropriate to refer to the system 100 of FIG. 2 as comprising “LEDs”, and the below discussion will sometimes make such reference.

The cooling power supply 235 supplies direct current (“DC”) voltage and current to a network or series of members, semiconductors, or conductors (also referred to as “TE elements” 210, 215 and interconnect 220) that cool the substrate 125 and the LEDs 175 attached thereto when electrically energized. The cooling circuit 250 comprises a system or circuit 250 of TE elements 210, 215 that extract heat from the substrate 125 to provide a beneficial thermal environment for the LEDs 175. The circuit 250 is referred to herein as a “TE circuit”. The TEC 150 can function in a capacity of an active heat pump.

The TE elements 210, 215 can respectively comprise two different materials or dissimilar metals that are in the electricity's path. The cooling power supply 235 provides a voltage differential across the two TE elements 210, 215 of dissimilar metals, causing a temperature differential that is similar to operating a thermal couple in reverse. In an exemplary embodiment, the temperature differential is a result of the Peltier effect, Peltier cooling, Peltier-Seebeck cooling, or a thermal electric effect. The TEC 150 typically comprises numerous junctions between dissimilar metals. Those junctions are electrically in series with one another and thermally in parallel with one another. As an alternative to having an intervening conductor 220 disposed between the two dissimilar metals as shown in FIG. 2, those metals can directly contact one another.

As an alternative to dissimilar or different metals, the TE circuit 250 can provide thermal regulation via semiconductor-based cooling. The TE elements 210, 215 can respectively be N- and P-type semiconductors with high Seeback coefficients, high thermal conductivity, high figure or merit, and/or low thermal resistance. The TE elements can comprise bismuth telluride, lead telluride, silicon germanium, or cobalt lead (not an exhaustive list). In one embodiment, the semiconductor materials can be layered in thin-films to create micro-sized devices that enhance cooling density without sacrificing cooling capacity.

In the illustrated exemplary embodiment, the TE elements 210, 215 are attached to electrical interconnects 220 that attach to the substrates 120, 125. In exemplary embodiments, the electrical interconnects 220 comprise metallic materials plated, coated, deposited, layered, or filmed on the substrates 120, 125. For example, the full surfaces 201, 208 of the substrates 120, 125 facing the TE circuit 250 can be plated. Following plating, acid etching can selectively remove regions of the plating so the electrical interconnects 220 remain. The TE members 210, 215 can then be attached, for example via welding, soldering, or bonding, to the patches of interconnect material layer that remain. Via such a process, the TE circuit 250 is in electrical and physical contact with the substrates 120, 125. More specifically, the TE circuit 250 touches and contacts the substrate surface 201, both physically and electrically. In one exemplary embodiment, physical and electrical contact results from urging or pressing the TE elements 210, 215 to the electrical interconnects 220, without necessarily incorporating permanent bonding.

In another exemplary embodiment, the TE circuit 250 can be formed as a separate structure that is attached to the substrates 120, 125. More specifically, a series network can be fabricated by welding, bonding, or otherwise attaching the TE elements 210, 215 to the interconnection elements 220, thus forming a stand-alone structure. That structure, which comprises the TE circuit 250, can be sandwiched between the two substrates 120, 125. The TE circuit 250, so formed, can be bonded, glued, welded, soldered, or otherwise attached (chemically, metallically, via heat, etc.) to the substrates 120, 125. Accordingly, the TE circuit 250 can adjoin, contact, or touch the substrates 120, 125 and specifically the substrate surface 201. Electricity flowing in the TE circuit 250 can thereby adjoin, contact, or touch each of the substrates 120, 125, and the substrates 120, 125 can electrically insulate the TE circuit 250. The electrical insulation of the substrate 120 prevents electrical shorting or unwanted/uncontrolled flow of electricity while providing thermal conductivity to improve TEC efficiency and to lower the junction temperature of the LEDs 175.

The heatsink 205 dissipates heat that the TEC 150 draws from the substrate 125 and the LEDs 175. A system of fins, channels, or grooves 203 comprises open areas through which air flows and circulates to promote convection. In an exemplary embodiment, the heatsink 205 can be made of aluminum or another metal with reasonably high thermal conductivity. In certain exemplary embodiments, the heatsink 205 comprises one or more heat pipes, a water cooler, or some other appropriate heat management system.

The outer surface 200 of the substrate 125, opposite the surface 201, comprises facilities for attaching the LEDs 175 thereto. In one exemplary embodiment, that surface 202 comprises pads 202 to which LEDs 175 are attached. In an exemplary embodiment, the pads 202 comprise a metal plating, coating, or layer. The material of the pads 202 can comprise copper, nickel, silver, gold, etc. In one embodiment, the surface 200 comprises a coat of nickel or other material that promotes adherence of a copper film to the substrate 125. The pads 202 can, in other words, comprise multiple layers of metal or other materials to support adhesion, bonding, etc.

The LEDs 175 can be soldered, bonded, or attached with electrically conductive adhesive, for example. With the LEDs 175 in “die” form, the die-to-substrate attachments and electrical connections can be implemented with eutectic bonds. The material of the eutectic bonds can comprise bismuth tin or some other material that supports low-temperature bonding. Epoxies can also be used to die bond the LED 175 to the substrate 125.

In addition to the pads 202, the surface 200 comprises electrical conductors in the form of electrical traces 275 that feed or provide electricity to the LEDs 175. The feed traces 275 can be defined via photolithography or via essentially any other known process or procedure for imprinting a surface with electrical conductors or elements.

The LEDs 175 are wirebonded to the feed trace 275 via one or more microwires 204. Wirebonding typically involves soldering each microwire, which can comprise gold, aluminum, or copper, for example. In certain exemplary embodiments, the LEDs 175 can be attached via flip-chip assembly.

The LEDs 175 of the lighting system 100 comprise semiconductor diodes emitting incoherent light when electrically biased in a forward direction of a p-n junction. In an exemplary embodiment, each LED 175 emits blue or ultraviolet light, and the emitted light excites a phosphor that in turn emits red-shifted light. The LEDs 175 and the phosphors emit blue and red-shifted light that essentially matches blackbody radiation and may approximate or emulate incandescent light to a human observer. In one exemplary embodiment, the LEDs 175 and their associated phosphors emit substantially white light that may seem slightly blue, green, red, yellow, orange, or some other color ting or tint. Exemplary embodiments of the LEDs 175 in the system 100 can comprise indium gallium nitride (“InGaN”) or gallium Nitride (“GaN”) for emitting blue light.

In an alternative embodiment, the system 100 can comprise LEDs 175 that individually produce distinct colors of light while collectively producing substantially white light or light emulating a blackbody radiator. Some of the LEDs 175 can produce red light, while others produce, blue, green, orange, or red, for example.

In certain exemplary embodiments, the lighting system 100 is controlled via RGB (Red-Green-Blue) and/or tri-stimulus methodology to create white or off-white light shifted to provide desired colors. For example, the lighting system 100 can support a range of desired colors, decorative lighting effects, theatrical light, or architectural aesthetics (not an exhaustive list). Furthermore, the lighting system's LEDs 175 can be controlled to provide color shifts for biological purposes, such as in support of day/night cycles.

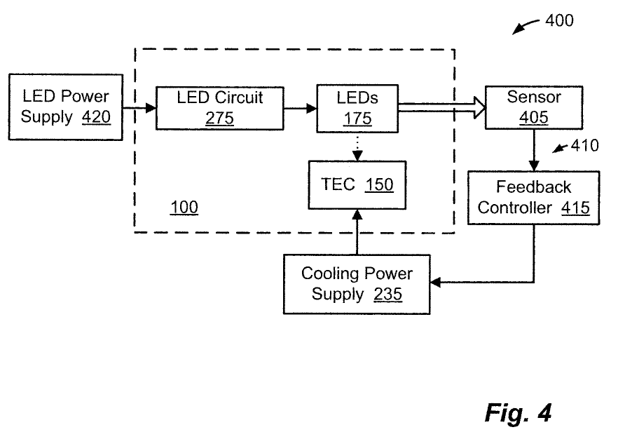

In one exemplary embodiment, active and passive electrical circuit components can be attached to the surface 200 in addition to the LEDs 175. For example, resistors, amplifiers, LED drivers, transistors, operational amplifiers, power supplies, sensors (including the sensor 405 illustrated in FIG. 4 an discussed below), digital logic circuits, etc. can be soldered or solder-bumped to the surface 200. Further, electrical or electronic components can be either surface mounted or attached to through-holes or vias of the substrate 125.

In one exemplary embodiment, optically transparent or clear material encapsulates the LEDs 175, either individually or collectively. Thus, one body of optical material can encapsulate the full LED array 175 illustrated in FIG. 1. The encapsulating material can comprise a conformal coating, a silicone gel, cured/curable polymer, acrylic, glass, adhesive, or some other material that protects the LEDs while transmitting light. Moreover, one body of such material can contact the surface 200; the electrical circuitry associated with the contact pad 130, the mounting pad 202, and the feed traces 275; the LEDs 175; and associated active electrical elements. In one exemplary embodiment, phosphors, for converting blue or ultraviolet light to light of another color, are coated onto or dispersed in the body of material.

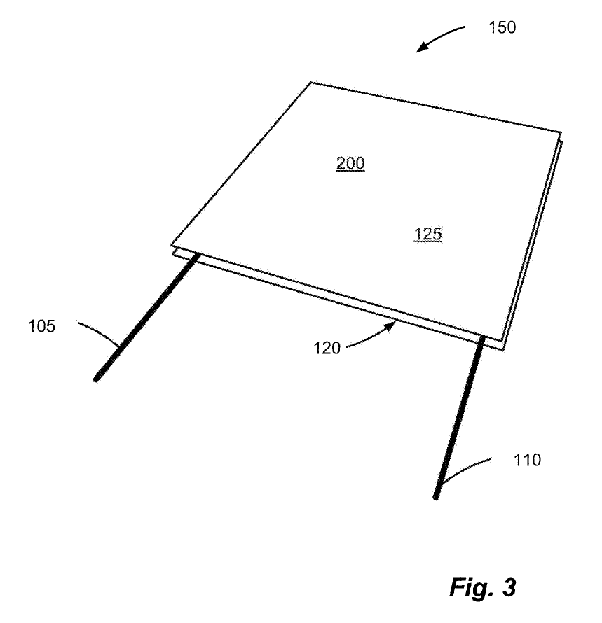

Turning now to FIG. 3, this figure illustrates a line drawing of an exemplary cooling system 150 that a lighting system 100 can comprise according to certain embodiments of the present invention. In an exemplary embodiment, the cooling system 150 can be the TEC 150 of FIGS. 1 and 2. In other words, FIG. 3 provides a perspective view of an example of the TEC 150 exemplarily illustrated in FIGS. 1 and 2.

In one exemplary embodiment, the TEC 150 of FIG. 3 is formed as a distinct step in manufacturing the lighting system 100. After fabricating the TEC 150, the circuitry, for example the feed traces 275, and LEDs 175 are applied to the surface 200, thereby creating the lighting system 100. In other words, LEDs 175 and other elements not shown in FIG. 3 can be attached directly to the TEC 150 illustrated in FIG. 3.

In an alternative exemplary embodiment, the feed traces 275 and LEDs 175 are applied to the surface 200 of the substrate 125 prior to integrating an active cooling capability to the substrate 200. Then, the TEC 150 is created from the substrate assembly. FIG. 5, discussed below, describes an exemplary embodiment of such a process.

Commercial suppliers of TEC components suitable for including in exemplary embodiments of the lighting system 100 and/or the TEC 150 include Custom Thermoelectic of Bishopville, Md.; Ferrotec (USA) Corporation of Santa Clara, Calif.; and Marlow Industries, Inc. of Dallas Tex.

Turning now to FIG. 4, this figure illustrates a functional block diagram of an exemplary thermally regulated lighting system 400 that comprises an LED 175 and a feedback loop 410 according to certain embodiments of the present invention. More specifically, FIG. 4 describes outfitting the system 100, discussed above, with a feedback loop 410 that controls the TEC 150 based at least in part on sensing light output by the LEDs 175. Alternatively, the feedback look 410 controls the TEC 150 via a thermal sensor, such as a thermometer, a thermocouple, a thermistor, or an RTD.

In one exemplary embodiment, the sensor 405 detects the level or intensity of light emitted by the LEDs 175, and the feedback loop 410 controls the TEC 150 to maintain LED intensity at a target level. In another exemplary embodiment, the sensor 405 detects the spectral content or color of the emitted light and adjusts the TEC 150 accordingly. Accordingly, the sensor 405 can comprise a simple light detector, an intensity meter, or a spectrometer. In one exemplary embodiment, the sensor 405 mounts on or otherwise attaches to the surface 125.

In one exemplary embodiment, the feedback loop 410 feeds a temperature target (or “setpoint”) to the cooling power supply 235, and the cooling power supply 235 supplies sufficient electricity to maintain the LEDs 175 at the target temperature. In an alternative exemplary embodiment, the feedback loop 410 adjusts the electrical output of the cooling power supply 235 based on sensed light, without direct temperature feedback.

In either case, the sensor 405 provides the feedback controller 415 with information about performance or operating status of the LEDs 175. In one exemplary embodiment, the feedback controller 415 comprises a proportional-plus-integral-plus-derivative (“PID”) controller, which may be based on digital or analog circuitry. In one exemplary embodiment, the feedback controller 415 comprises a proportional-plus-integral (“PI”) controller, implemented via digital logic or an analog circuit. In one exemplary embodiment, the feedback controller 415 comprises a computer or microprocessor that controls the lighting system 100 according to programming instructions stored in memory.

The feedback controller issues instructions or prompts to the cooling power supply 235 that adjust the amount of electricity (e.g. current and/or voltage) delivered to the TEC 150. The electrical adjustments control the temperature of the LEDs 175 so the LEDs operate in a temperature region that provides power efficiency and long life.

Dynamically controlling or regulating the operating temperature of the LEDs 175 can further compensate for variations in the LED power supply 420. For example, a user may dim the LEDs 175 via modulating the time duration of current pulses delivered by the LED power supply 420 to the LEDs 175, in a process that can be described as “pulse width modulation”. The dimmed LEDs 175 generate less heat than they would at their full brightness. The feedback controller 415 adjusts the amount of heat extracted from the substrate 200 so the LEDs 175 continue to operate in favorable temperature conditions. Accordingly, the feedback controller 415 can compensate for changes in the LEDs 175, whether such changes are due to user adjustments, aging of the LEDs 175, ambient light, random fluctuations in the LED power supply 420, environmental influences due to seasonal or other changes, or some other variation.

Turning now to FIG. 5, this figure illustrates a flowchart of an exemplary process 500 for fabricating a lighting system 100 that comprises an LED 175 and a capability for cooling the LED 175 according to certain embodiments of the present invention. In an exemplary embodiment, the process 500, which is entitled “Fabricate Cooled LED Lighting System”, comprises a method for mass producing the lighting system 100 depicted in FIGS. 1 and 2. Accordingly, reference will be made to the lighting system 100 while discussing the exemplary steps of process 500.

As discussed above, one exemplary method for fabricating the lighting system 100 comprises attaching circuitry, for example the contact pads 130, the feed traces 275, and the mounting pad 202, on top of a previously constructed TEC 150. However, process 500 offers an alternative approach. Exemplary process 500 proceeds via first applying such circuitry to a ceramic substrate 125 and then applying an active cooling capability to the circuit-substrate assembly.

At step 505, an electrical or electronic circuit is printed on or otherwise added to the ceramic substrate 125, typically as a separate sheet or plate of ceramic material.

In an exemplary embodiment of step 505, a manufacturer or a fabricator procures a flat piece of ceramic material that is suitable stock for creating a ceramic circuit board. To facilitate making multiple lighting systems 100, the flat piece of ceramic material can comprise a ceramic wafer large enough to yield multiple lighting system substrates 125.

The fabricator plates one side of the ceramic stock with a conductive material such as copper, gold, silver, etc. An application of photoresist, or other material that responds to light, readies the stock for photolithography and etching. An engineer creates a circuit layout using circuit-design software executing on a personal computer. The personal computer exports the circuit layout to a photolithographic system. The photolithographic system projects the circuit image (or a negative thereof) onto the metal-plated stock and the photoresist coating. Typically, the system projects multiple images, displaced from one another, onto the ceramic stock.

Submerging the ceramic stock in an acid bath etches selective areas of metal plating according to the projected images. When etching completes, the desired circuit pattern remains, in a metallic pattern. A solvent wash removes residual photoresist. Multiple instances of the desired circuitry are thereby patterned onto one wafer of the ceramic stock.

Dicing the stock, for example with a diamond saw, between each circuit pattern yields multiple copies of the desired circuit. Accordingly, one large wafer of ceramic stock produces numerous circuits. Each patterned piece of ceramic or “die” can be the substrate 125 incorporating the circuit patterns 130, 275, 202.

At step 510 of process 500, the fabricator attaches one or more LEDs 175 to each patterned ceramic substrate 200. As discussed above with reference to FIG. 2, die bonding and wire bonding machinery attaches the LEDs 175 as well as supporting active and passive electronic components, to the surface 200. In an alternative exemplary embodiment, manual or automatic soldering, or some other attachment technique known in the art, attaches the circuit elements to the surface 200 of the substrate.

At step 515, the fabricator attaches TE circuit 250, including the TE elements 210, 215, to each ceramic substrate 125, specifically on the side 201 opposite from the LEDs 175. As discussed above, exemplary procedures for making this attachment can comprise soldering, gluing, applying ceramic adhesives or refractory bonding agents, welding, etc.

At step 520, the fabricator attaches another ceramic substrate 120 to each TE circuit 250, with the TE circuit sandwiched between the two ceramic substrates 120, 125. This attachment can comprise applications of glue, ceramic adhesive, solders, brazes, or fasteners, for example. In one exemplary embodiment, the TE circuit 250 is pressed between the two ceramic substrates 120, 125 with compression force holding the assembly together. Thus, one or more mechanical fasteners hold the assembly together without glues or adhesives.

At step 525, the fabricator attaches the heatsink 205 to each ceramic substrate 120 opposite from the TE circuit 250. A intermediate layer of thermally conductive adhesive, thermal interface material (“TIM”), tape, or material can promote thermal transfer from the ceramic substrate 120 to the heatsink 205.

Process 500 ends following step 525. Via processing the substrates in batches, particularly at step 505, process 500 yields numerous copies of the system 100 with a high level of manufacturing efficiency.

Turning now FIG. 6, this figure illustrates a flowchart of an exemplary process 600 of operation of a lighting system 100 that comprises an LED 175 and a capability for cooling the LED 175 according to certain embodiments of the present invention. In an exemplary embodiment, process 600 comprises a method for producing light with a lighting system 100 produced by process 500 as discussed above.

At step 605 of process 600, the cooling power supply 235 delivers electrical power to the TEC 150. In response to the electrical power, the TEC 150 actively extracts heat from the substrate 125, effectively reducing the temperature of the substrate 125 and the LEDs 175 attached thereto. As discussed above, the heat extraction can comprise pumping heat, TE cooling, utilizing Peltier cooling, passing electricity through semiconductor materials that produce a cooling effect, or some other means for actively removing heat known in the art.

At step 610, the LED power supply 420 delivers electrical current to the LEDs 175 via circuit traces (for example the contact pads 130) printed on the surface 200 at step 505 of process 500. The current can be pulsed or continuous and can be pulse width modulated to support user-controlled dimming. In response to the applied current, the LEDs 175 emit or produce substantially white light or some color of light that a person can perceive. As discussed above, in one exemplary embodiment, at least one of the LEDs 175 produces blue or ultraviolet light that triggers photonic emissions from a phosphor. Those emissions can comprise green, yellow, orange, and/or red light, for example.

In response to the environmental conditions provided by the TEC 150, the LEDs 175 operate efficiently and avoid premature failure. In an exemplary embodiment, the mean time before failure or average life of the LEDs 175 can exceed 50,000 hours in the thermal conditions provided by the TEC 150.

At step 615, the sensor 405 detects a portion of the light the LEDs 175 emit. In an exemplary embodiment, the sensor 405 determines light intensity from the LEDs 175 or light intensity in the vicinity of LEDs 175. The sensor 405 feeds an electrical signal carrying the intensity information to the feedback controller 415.

As an alternative to light intensity, the sensor 405 can detect another parameter that provides operational feedback about the LEDs 175. In certain exemplary embodiments, the sensor 405 comprises an RTD, a thermistor, a thermocouple, or some other means for measuring or assessing temperature of the LEDs 175. In certain exemplary embodiments, the sensor 405 comprises a component measuring a voltage associated with the LEDs 175 to provide an indication of operational state, temperature, performance, etc. of the LEDs 175. For example, the sensor 405 can sense a secondary voltage V_{f} of the LEDs 175 as an indication of the LEDs' operational temperature.

At step 620, the feedback controller 415 prompts the cooling power supply 235 to output electrical power to the TEC 150 according to the sensor input. When ambient temperature drops in the winter, for example, the cooling power supply 235 may decrease the power output to compensate for increased ambient cooling. Similarly, the feedback controller 415 can set the cooling power supply 235 to compensate for age-related degradation, changes in the electrical characteristics of the power supply 420, failure of one or more LEDs 175, chromatic changes, etc.

More generally, at step 620, the feedback control loop 410 regulates or manipulates the temperature of the LEDs 175 so that the LEDs 175 operate within a particular band of thermal conditions, despite fluctuating conditions, random events, and various perturbations.

Process 600 ends following step 620. In an exemplary embodiment, the LEDs 175 provide efficient illumination for many years.

Technology for cooling an LED of an illumination system, for fabricating an illumination system that comprises a cooled LED, and for operating such an illumination system has been described. From the description, it will be appreciated that an embodiment of the present invention overcomes the limitations of the prior art. Those skilled in the art will appreciate that the present invention is not limited to any specifically discussed application or implementation and that the embodiments described herein are illustrative and not restrictive. From the description of the exemplary embodiments, equivalents of the elements shown therein will suggest themselves to those skilled in the art, and ways of constructing other embodiments of the present invention will appear to practitioners of the art. Therefore, the scope of the present invention is to be limited only by the claims that follow.

What is claimed is:

1. An illumination system comprising:
a plate comprising a material that promotes heat conduction and inhibits flow of electricity, said plate having a first side and a second side;
an electrical circuit, adjoining the first side of the plate, that is operative to cool the plate when electrically energized; and
a light emitting diode adjoining the second side of the plate.

2. The illumination system of claim 1, further comprising solder that attaches the light emitting diode to the second side of the plate.

3. The illumination system of claim 1, wherein the electrical circuit comprises:
an electrical conductor adjoining the first side of the plate; and
a first metal and a second metal, each attached to the electrical conductor, that are operative to draw heat from the plate in response to electrical energization.

4. The illumination system of claim 1, further comprising a pattern of electrical traces, printed on the second side of the plate, that are operative to supply electrical current to the light emitting diode.

5. The illumination system of claim 1, wherein the second side of the plate is patterned with electrical traces for energizing the light emitting diode, and wherein the light emitting diode is attached to one of the traces via a solder bump.

6. The illumination system of claim 1, wherein the plate comprises a metallic film disposed on the second side of the plate, and wherein the light emitting diode is surface mounted to the metallic film.

7. The illumination system of claim 1, wherein the plate comprises a patch of electrically conductive material attached to the second side of the plate, and wherein the light emitting diode is soldered or bonded to the metallic film.

8. A lighting system comprising:
a substrate that comprises ceramic material and that has a first side and a second side;
a light emitting diode attached to the first side via solder; and
an electrical conductor bonded directly to the second side and operable to conduct heat away from the second side in response to electricity flowing through the electrical conductor.

9. The lighting system of claim 8, further comprising a patch of electrically conductive material adjoining the first side, wherein the light emitting diode is soldered to the patch, and wherein the light emitting diode is operative to emit substantially white light.

10. The lighting system of claim 8, wherein the substrate further comprises a first metallic plating on the first side, and wherein the electrical conductor comprises a second metallic plating on the second side.

11. The lighting system of claim 8, further comprising two different metals in electrical communication with the electrical conductor that are operative to draw the heat from the substrate in response to transmitting the electricity.

12. The lighting system of claim 8, further comprising a semiconductor or dissimilar metallic materials attached to the electrical conductor that cool the light emitting diode via the Peltier effect.

13. The lighting system of claim 8, further comprising:
another substrate that comprises ceramic material; and
a heatsink, wherein the electrical conductor is sandwiched between the substrate and the another substrate, and wherein the heatsink is attached to the another substrate.

14. An illumination apparatus comprising:
a thermoelectric cooler that comprises:
a plate comprising a material that is electrically insulative and thermally conductive, said plate having a first side and a second side; and
a first piece of metal and a second piece of metal that each adjoins the second side of the plate and that are operative to cool the plate in response to a transmission of electricity; and
a light emitting diode adjoining the first side of the plate.

15. The illumination apparatus of claim 14, wherein the plate further comprises:
a first patterned conductive coating applied to the first side; and
a second patterned conductive coating applied to the second side, wherein the light emitting diode is soldered to the first patterned conductive coating, wherein a first section of the second patterned conductive coating comprises the first piece of material, and wherein a second section of the second patterned conductive coating comprises the second piece of material.

16. The illumination apparatus of claim 14, wherein the first piece of metal and the second piece of metal are bonded to the second side of the plate;
wherein the plate comprises a sheet of ceramic material; and
wherein the first piece of metal and the second piece of metal comprise dissimilar metals.

17. The illumination apparatus of claim 14, wherein the material comprises ceramic material,
wherein the first side of the plate is patterned with circuit traces that supply electricity to the light emitting diode, and
wherein the light emitting diode comprises a phosphor for converting blue or ultraviolet light into light spectrally shifted towards red.

18. A method, for fabricating a lighting system, comprising the steps of:
sandwiching two different metals between a first and a second plate, wherein the two different metals are operative to transfer heat from the first plate to the second plate in response to a transmission of electricity through the two different metals, and wherein each of the first and the second plates is operative to conduct heat while insulating electricity;
applying an electrically conductive pad to the first plate on a surface opposite the two different metals; and
attaching a light emitting diode to the electrically conductive pad.

19. The method of claim 18, wherein the step of sandwiching two different metals comprises touching an electrical circuit, comprising the two different metals, to the first plate.

20. The method of claim 18, wherein the step of applying the electrically conductive pad comprises patterning the surface via photolithography.

21. The method of claim 18, wherein attaching the light emitting diode to the electrically conductive pad comprises soldering the light emitting diode.

22. A method for fabricating a lighting device, comprising:
adjoining an electrical conductor to a first side of a sheet of ceramic material;
placing the electrical conductor in electrical series with two different materials that cool the sheet of ceramic material in response to transmitting electricity; and
adjoining a light emitting diode to the second side of the sheet of ceramic material.

23. The method of claim 22, wherein placing the electrical conductor in electrical series with two different materials comprises placing the electrical conductor in electrical series between the two different materials, and wherein each of the two different materials comprises a semiconductor.

24. The method of claim 22, wherein the step of adjoining the light emitting diode to the second side comprises defining a conductive pattern on the second side via photolithography; and
soldering the light emitting diode to the defined pattern.

25. The method of claim 22, wherein the step of adjoining the electrical conductor to the first side comprises bonding the electrical conductor to the first side.
